(19) United States
(12) Patent Application Publication
(10) Pub. No.: US 2019/0181282 A1
(43) Pub. Date: Jun. 13, 2019

(54) MANUFACTURING METHOD OF PATTERN LAYER OF SOLAR PANEL AND STRUCTURE THEREOF

(71) Applicants: TSAI-HUI CHEN, Nantou County (TW); TSUI-HUANG LI, Taichung City (TW)

(72) Inventors: TSAI-HUI CHEN, Nantou County (TW); TSUI-HUANG LI, Taichung City (TW)

(21) Appl. No.: 15/839,212

(22) Filed: Dec. 12, 2017

(51) Int. Cl. H01L 31/048; H01L 31/0216; H01L 31/0203; H01L 31/18; H02S 20/25; H02S 40/20; B32B 17/10

(52) U.S. Cl. CPC H01L 31/048; H01L 31/02168; H01L 31/0203; B32B 17/10788; H02S 20/25; H02S 40/20; H01L 31/18

(57) ABSTRACT

A manufacturing method of pattern layer of solar panel and the structure thereof, with the solar panel having a substrate, a power generating layer disposed on the substrate, and a transparent pattern layer covering the power generating layer, wherein the method comprises: a selecting step, which comprises selecting a base panel having said substrate and the power generating layer, and an rated electricity of the base panel is larger than an electricity actually required; and a surface disposition step, which comprises disposing the transparent pattern layer onto a surface of the base panel, wherein the thickness of the transparent pattern layer is changed according to predetermined colors and transparency of different areas of the transparent pattern layer, so as to maintain an even transparency for light to evenly enter the solar panel.

### BACKGROUND OF THE INVENTION

### (1) Field of the Invention

The present invention is related to a manufacturing method of pattern layer of solar panel and structure thereof, and specifically to a method increasing the colorfulness of a surface pattern layer of a solar panel and improving the power generating efficiency thereof.

### (2) Description of Related Art

With the growth in sustainable energy technologies, solar power technology and system thereof has been the most popular, mature and widely used one of them. Conventionally, solar panels are arranged in positions outside the building for a sufficient amount of insolation. However, in metropolitan areas with high land price, users usually decide to settle solar panels on the roofs of housings or mansions, which are not designed for people to frequently exist and have limited area. Unfortunately, since the power generating efficiency is extremely related to the total area of the solar panels, how to persuade buildings' or mansions' owners to willingly increase areas for the arrangement of solar panels is the primary issue in solar power technology currently.

The main reason why the current users of solar panels prefer to settle these panels in positions not designed for people to frequently exist is that the outer surfaces of conventional solar panels are usually black, monotonous, and not artistic. Since there is almost no other choice in the outward appearance thereof, it is impossible to largely increase the disposition area of solar panels in surfaces of a building such as outer walls or windows, which are usually adapted for advertising or decoration without power generating effect. Apparently, if it is possible to set solar panels on said outer walls or windows of buildings, the electrical power generated thereby should be enormous.

Please refer to FIG. 1 showing a photo of the patterned surface of a conventional solar panel. In need of enriching the colorfulness of solar panels, some solar panels with various colors are provided in the market. This kind of solar panel provides visual performance on its surfaces by reflected rays bent into difference directions due to the original color of the solar panel, different parts of the surface facing various directions and height differences in the refined surfaces. The way to form said different parts and height differences in this conventional art is by etching the surfaces during refining them. As a result, most of surface shows the same color category, with varied brightness. Similarly, the pattern shown thereon is also a result of the height differences and the parts facing various directions, which is usually not a complicated one or a combination of different colors.

Furthermore, a coloring technology for solar panels is disclosed by an US patent with a patent publication number of 2010/0282318, especially in paragraph [0063] and FIG. 9 thereof. The literal disclosures are “the lower surface encapsulant resin layer 120 is covered by a backing plate 124. In this embodiment of the present invention, the upper surface encapsulant resin layer 116 is covered with an infrared transmissive overlay film 126. The lower surface of the overlay film 126 is provided with a three-dimensional pattern simulating the appearance of roofing granules on a conventional roofing shingle” and “the upper surface of the overlay film 126 is covered with a top plate 118, and adhered to the lower surface of the top plate 118 by a thin film 128 of infrared transmissive adhesive material.” It is apparent that the vision appearance formed by this coloring technology, that is, letting the reflected rays go through the 3D pattern on the overlay film 126, is still in the same color category. The pattern provided by this conventional coloring technology is unable to show a complicated content or a combination of different colors.

### BRIEF SUMMARY OF THE INVENTION

A manufacturing method of pattern layer of solar panel, with the solar panel having a substrate, a power generating layer disposed on the substrate, and a transparent pattern layer covering the power generating layer, wherein the method comprises: a selecting step, which comprises selecting a base panel having said substrate and the power generating layer, and an rated electricity of the base panel is larger than an electricity actually required; a surface disposition step, which comprises disposing the transparent pattern layer onto a surface of the base panel, wherein the thickness of the transparent pattern layer is changed according to predetermined colors and transparency of different areas of the transparent pattern layer, so as to maintain an even transparency for light to evenly enter the solar panel.

A manufacturing method of pattern layer of solar panel, comprising: a selecting step, which comprises selecting a base panel having said substrate and the power generating layer, and an rated electricity of the base panel is larger than an electricity actually required; a base disposition step, which comprises evenly disposing a plurality of transparent dots on a surface of the base panel to form a base layer, wherein a plurality of particles able to provide light reflection effect is embedded in the dots, a spacing distance is formed between any two adjacent ones of the evenly disposed dots, a transparency of the transparent dots allows an incoming ray to split into a reflected ray and an incident ray due to the reflection effect of the particles, the dots form bulges on the surface of the base panel to provide an enlarged capacity for receiving said particles and an enlarged surface area for light to enter the solar panel; and a surface disposition step, which comprises disposing a plurality of pieces of a surface layer onto the base layer, wherein each piece of the surface layer has a color the same with or different from others, and thicknesses of the pieces of the surface layer are the same or different from each other according to colors thereof, so that the solar panel has a colorful appearance by a combination of various patterns, lines and colors.

A solar panel with pattern layer, with said solar panel having a substrate and a power generating layer and further comprising: a plurality of transparent dots made of transparent material evenly disposed on a surface of the power generating layer to form a base layer, wherein a plurality of particles in a predetermined number is embedded in the dots, with said particles providing light reflection effect and made of a material with light reflection capability, wherein a spacing distance is formed between any two adjacent ones of the evenly disposed dots, thus the transparent dots allow incoming rays to split into reflected rays and incident rays due to the reflection effect provided by the particles, wherein the dots form bulges on the surface of the power generating layer, and wherein said bulges of the base layer increase the surface area thereof thus increase an amount of the incoming rays entering the base layer; and a surface layer in a form of a plurality of pieces, wherein said pieces are evenly disposed on the plurality of dots, and wherein each piece of the surface layer has a color the same with or different from others, and thicknesses of the pieces of the surface layer are the same or different from each other according to colors thereof, so that the solar panel has a colorful appearance by a combination of various patterns, lines and colors surface-treating step

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

It should be noted that the drawing figures may be in simplified form and might not be to precise scale. In reference to the disclosure herein, for purposes of convenience and clarity only, directional terms, such as, top, bottom, left, right, up, down, over, above, below, beneath, rear, front, distal, and proximal are used with respect to the accompanying drawings. Such directional terms should not be construed to limit the scope of the invention in any manner.

FIG. 1 is a top view of a conventional solar panel.

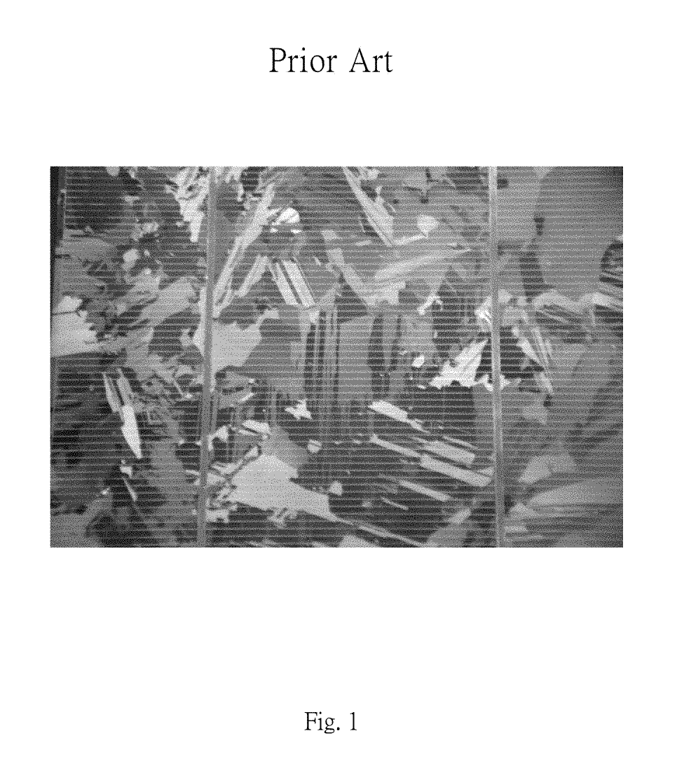

FIG. 2 is a sectional side view of a first embodiment of a present disclosure.

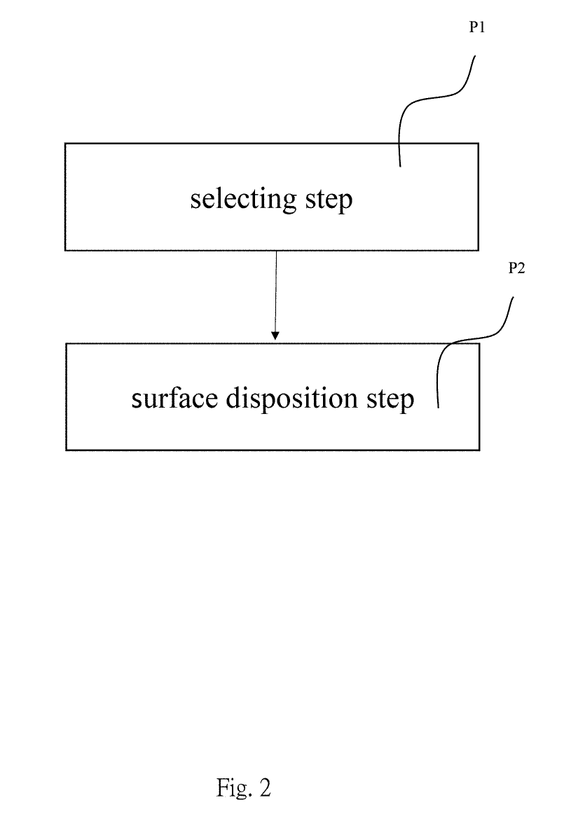

FIG. 3 is a flow chart of a manufacturing method of the first embodiment of the present disclosure.

FIG. 4 is a flow chart of a manufacturing method of a second embodiment of the present disclosure.

FIG. 5 is sectional side view of the second embodiment of the present disclosure.

FIG. 6 is a detailed sectional side view of the second embodiment of the present disclosure.

FIG. 7 is another detained sectional side view of a third embodiment of the present disclosure.

FIG. 8 is another detailed sectional side view of the second embodiment of the present disclosure.

### DETAILED DESCRIPTION OF THE INVENTION

The invention and its various embodiments can now be better understood by turning to the following detailed description of the preferred embodiments, which are presented as illustrated examples of the invention defined in the claims. It is expressly understood that the invention as defined by the claims may be broader than the illustrated embodiments described below.

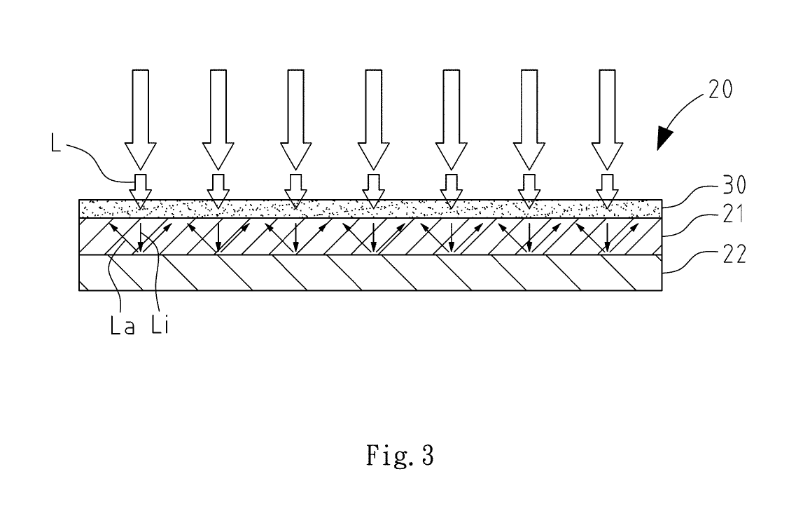

Referring to FIG. 3, the structure of a solar panel of a first embodiment of the present disclosure is shown, which includes a substrate 22, a power generating layer 21 disposed on the substrate 22, and a transparent pattern layer 30 covering the power generating layer 21, wherein a combination of the power generating layer 21 and the substrate 22 may be a conventional solar panel and is called a base panel 20 for the convenience of illustration hereinafter. In this embodiment, the transparent pattern layer may be a transparent film or any other layer made of flexible transparent material. Specifically, the transparent pattern layer 30 has gone through a process to form a colorful pattern, such as dyeing, coating or attachment, and a predetermined transparency demand of the transparent pattern layer 30 is required. Particularly, the predetermined transparency demand is that incoming rays L entering said solar panel can still form sufficient illumination to the power generating layer 21 for electrical power. Said illumination may be provided by incident rays Li entering the power generating layer 21 from the transparent pattern layer 30, or by reflected rays La entering the power generating layer 21 from the substrate 22.

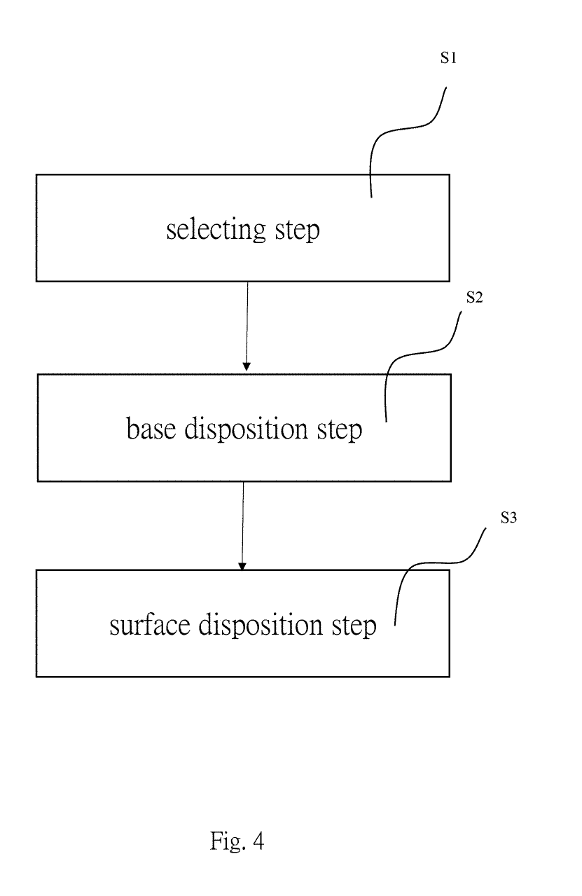

Please refer to FIG. 4, a flow chart of the manufacturing method of the first embodiment. In order to form a solar panel able to generate electrical power efficiently as well as to provide a colorful appearance, the way to from the transparent pattern layer 30 on the base panel 20 is discussed as follows.

First of all, a selecting step P1 is performed, which is selecting a base panel 20 matching the electrical power requirement of the user. Said base panel 20 has the substrate 22 and the power generating layer 21 thereon, and the default rated electricity EP1 generated by the base panel 20 is larger than the required electricity EP2 actually demanded from the user.

A surface disposition step P2 is then performed. In this step, a surface layer 12 is disposed onto an outer surface of the base panel 20 to form the transparent pattern layer 30 on the base panel 20. In order to provide a combination of various patterns, lines and colors on the solar panel of the present disclosure, as well as to provide an even transparency to the whole transparent pattern layer 30 for the base panel 20 to evenly transfer the entered rays into electrical power, the thickness of the transparent pattern layer 30 is changed according to the color 31/32 and the transparency of the used material. Namely, the transparent pattern layer 30 with areas in different colors may have a varied thickness. As a result, the present solar panel can be provided with a colorful appearance by the combination of various patterns, lines and colors, and its transparent pattern layer 30 can maintain the incident rays Li to evenly illustrate the base panel 20.

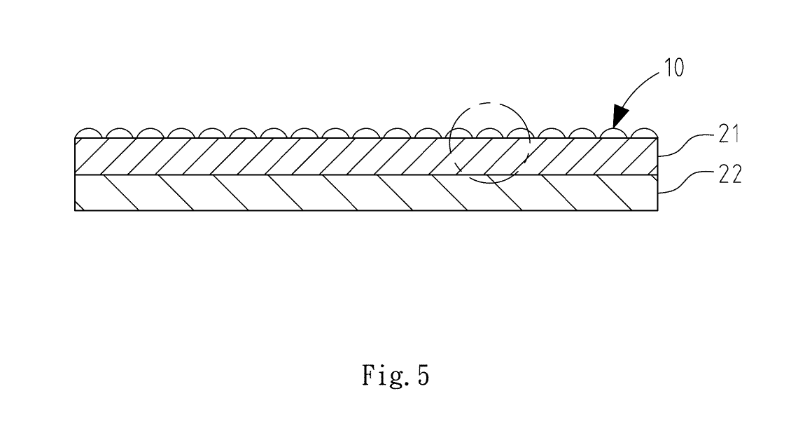

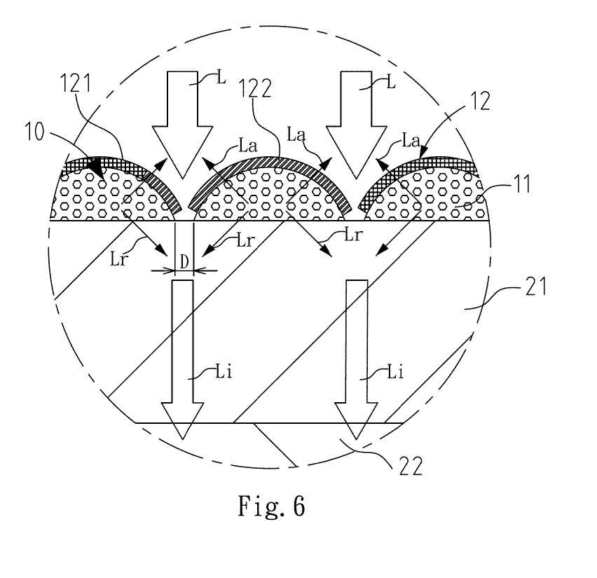

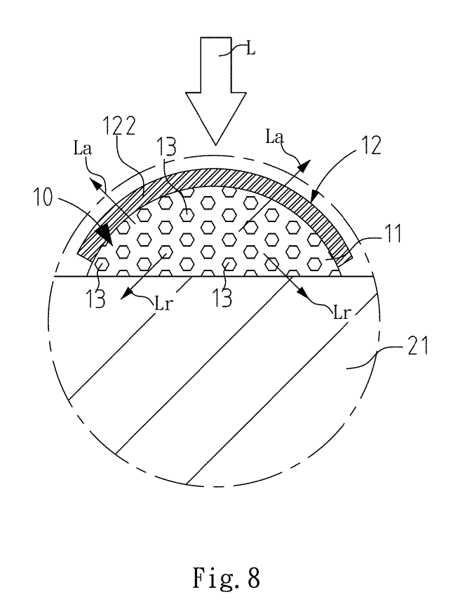

Please refer to FIGS. 5-8, which illustrate a second embodiment of the present disclosure. In order to form a solar panel able to generate electrical power efficiently as well as to provide a colorful appearance, a way to from a pattern layer 10 on the base panel 20 is discussed as follows.

A selecting step S1 is performed, which is selecting a base panel 20 matching the electrical power requirement of the user. Said base panel 20 has the substrate 22 and the power generating layer 21 thereon, and the generated electricity EP1 of the base panel 20 is larger than the required electricity EP2 actually demanded from the user.

A base disposition step S2 is then performed. A plurality of transparent dots 11 made of transparent silicone or the like is evenly disposed on the surface of the base panel 20 to form a base layer. Specifically, a plurality of particles 13 in a predetermined number is embedded in the dots 11, and said particles 13 are able to provide light reflection effect and may be made of metal or materials with light reflection capability. There is a spacing distance D between any two adjacent ones of the evenly disposed dots 11. Thereby, the transparency of the transparent dots 11 allows an incoming ray L to split into a reflected ray La and an incident ray Li due to the reflection effect provided by the particles 13. Moreover, the dots 11 form bulges on the surface of the base panel 20, so that the thickness of the pattern layer 10 increases at where the dots 11 locate, thus the particles 13 can be received in the thickened parts of the pattern layer 10. Furthermore, said bulges of the pattern layer 10 can also increase the surface area thereof to increase the amount of incoming rays L entering the pattern layer 10 for the particles 13 to reflect.

A surface disposition step S3 is then further performed. In this step, a plurality of pieces of a surface layer 12 is disposed onto the outer surfaces of the dots 11 at least. It is preferable that said pieces of the surface layer 12 are evenly and respectively disposed on the dots 11. However, it is not necessary that each piece of the surface layer 12 completely or perfectly matches only one of the dots 11. Each piece of the surface layer 12 has its color the same with or different from others, and the thicknesses of the pieces of the surface layer 12 may be different according to the various colors 121/122. As a result, the present solar panel can be provided with a colorful appearance by the combination of various patterns, lines and colors.

In this embodiment, after said three steps S1-S3, the pattern layer 10 is completed by the surface layer 12 and a base layer formed by the transparent dots 11. With the transparency of the surface layer 12, incoming rays L may enter the base panel 20 via the pieces of surface layer 12 or the gap forming the spacing distance D. A part of the incoming rays L enters the transparent dots 11 and is split into reflected rays La and refracted rays Lr, and the light for generating the required electricity EP2 is provided by the other part of the incoming rays L entering the base panel 20 via the gap and the refracted rays Lr. Specifically, with the gap forming the spacing distance D, the solar panel of this embodiment may improve the power generating efficiency relatively to the one of the first embodiment.

Specifically, since people tell the color of an object by accumulating discontinuous visual information carried by optic nerves to the brain instead of continuously receiving light as well as the solar panel continuously transfers light into electrical power, the reflected rays La generated by the plurality of particles 13, which have a large total area and various orientations and are inside the transparent dots 11, can provide a brightened color to an observer after they penetrate the surface layer 12 thereon. Furthermore, through the gap forming the spacing distance D, the illustration provided by the incoming light L to the solar panel is enhanced.

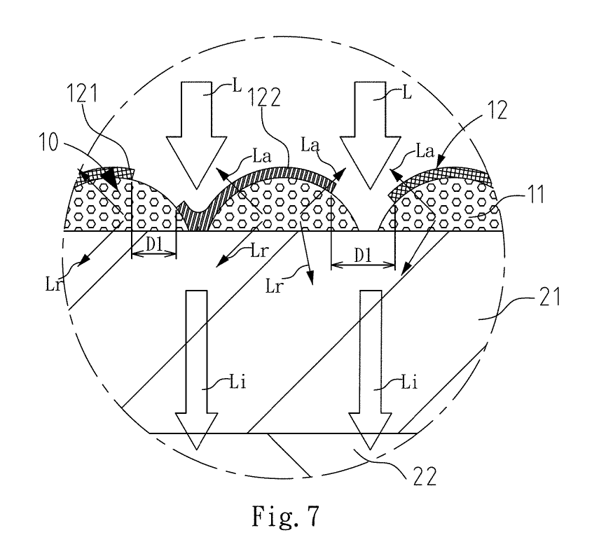

Particularly, please refer FIG. 7 again. Due to the small sizes of the transparent dots 11 and the pieces of the surface layer 12 which may lead to the gap between said pieces too small tr naked eyes to tell, the pieces of the surface layer 12 may not perfectly match the transparent dots 11 in the surface disposition step S3, thus the locations of the gaps forming the spacing distance D1 may be different in height. However, since the key point for the solar panel to stably generate power lies in that the illustration toward unit areas of the power generating layer 21 are even, the unmatched dots 11 and pieces do not affect the power generating efficiency at all. With the above design, that is, the embedded particles 13 inside the transparent dots 11 to reflect light and to form the reflected rays La, the gaps forming the different spacing distances D1 can allow the incoming rays L to illustrate a number of the particles 13 more than that illustrated in the first embodiment. Accordingly, the dispersion of the incident ray Li is even, thus the colors of the pattern layer 10 is brightened as well as the actually generated electricity EP2 is increased.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed herein even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Insubstantial changes from the claimed subject matter as viewed by a person with ordinary skill in the art, now known or later devised, are expressly contemplated as being equivalent within the scope of the claims. Therefore, obvious substitutions now or later known to one with ordinary skill in the art are defined to be within the scope of the defined elements. The claims are thus to be understood to include what is specifically illustrated and de+scribed above, what is conceptually equivalent, what can be obviously substituted and also what essentially incorporates the essential idea of the invention.

What is claimed is:

1. A manufacturing method of pattern layer of solar panel, with the solar panel having a substrate, a power generating layer disposed on the substrate, and a transparent pattern layer covering the power generating layer, wherein the method comprises:
a selecting step, which comprises selecting a base panel having said substrate and the power generating layer, and an rated electricity of the base panel is larger than an electricity actually required; and
a surface disposition step, which comprises disposing the transparent pattern layer onto a surface of the base panel, wherein the thickness of the transparent pattern layer is changed according to predetermined colors and transparency of different areas of the transparent pattern layer, so as to maintain an even transparency for light to evenly enter the solar panel.

2. The manufacture method of pattern layer of solar panel as claimed in claim 1, wherein the transparent pattern layer is a layer made of a flexible transparent material, has gone through a process to form a colorful pattern, and covers the power generating layer under a predetermined transparency demand.

3. The manufacture method of pattern layer of solar panel as claimed in claim 2, wherein the process forming the colorful pattern is dyeing, coating or attachment.

4. A manufacturing method of pattern layer of solar panel, comprising:
a selecting step, which comprises selecting a base panel having said substrate and the power generating layer, and an rated electricity of the base panel is larger than an electricity actually required;
a base disposition step, which comprises evenly disposing a plurality of transparent dots on a surface of the base panel to form a base layer, wherein a plurality of particles able to provide light reflection effect is embedded in the dots, a spacing distance is formed between any two adjacent ones of the evenly disposed dots, a transparency of the transparent dots allows an incoming ray to split into a reflected ray and an incident ray due to the reflection effect of the particles, the dots form bulges on the surface of the base panel to provide an enlarged capacity for receiving said particles and an enlarged surface area for light to enter the solar panel; and
a surface disposition step, which comprises disposing a plurality of pieces of a surface layer onto the base layer, wherein each piece of the surface layer has a color the same with or different from others, and thicknesses of the pieces of the surface layer are the same or different from each other according to colors thereof, so that the solar panel has a colorful appearance by a combination of various patterns, lines and colors.

5. The manufacturing method of pattern layer of solar panel as claimed in claim 4, wherein the plurality of particles is made of metal or a material with light reflection capability.

6. The manufacturing method of pattern layer of solar panel as claimed in claim 4, wherein the transparent dots are bulges formed on the surface of the base panel.

7. The manufacturing method of pattern layer of solar panel as claimed in claim 4, wherein the locations of the gaps forming the spacing distance are different in height.

8. A solar panel with pattern layer, with said solar panel having a substrate and a power generating layer and further comprising:
a plurality of transparent dots made of transparent material evenly disposed on a surface of the power generating layer to form a base layer, wherein a plurality of particles in a predetermined number is embedded in the dots, with said particles providing light reflection effect and made of a material with light reflection capability, wherein a spacing distance is formed between any two adjacent ones of the evenly disposed dots, thus the transparent dots allow incoming rays to split into reflected rays and incident rays due to the reflection effect provided by the particles, wherein the dots form bulges on the surface of the power generating layer, and wherein said bulges of the base layer increase the surface area thereof thus increase an amount of the incoming rays entering the base layer; and
a surface layer in a form of a plurality of pieces, wherein said pieces are evenly disposed on the plurality of dots, and wherein each piece of the surface layer has a color the same with or different from others, and thicknesses of the pieces of the surface layer are the same or different from each other according to colors thereof, so that the solar panel has a colorful appearance by a combination of various patterns, lines and colors surface-treating step.

9. The solar panel with pattern layer as claimed in claim 8, wherein each bulge formed on the power generating layer provides an enlarged capacity for receiving said particles and an enlarged surface area for light to enter the solar panel.
